(19) United States
(12) Patent Application Publication
(10) Pub. No.: US 2023/0396046 A1
(43) Pub. Date: Dec. 7, 2023

(54) HOUSING FOR AN ELECTRONIC DEVICE

(71) Applicant: OSRAM GmbH, Munich (DE)

(72) Inventors: Federico RUGGER, Baierbrunn (DE); Markus HECKMANN, Munich (DE); Peter SACHSENWEGER, Neutraubling (DE)

(21) Appl. No.: 18/323,452

(22) Filed: May 25, 2023

(30) Foreign Application Priority Data
Jun. 2, 2022 (DE) 102022113975.1

(51) Int. Cl. H02G 3/08

(52) U.S. Cl. CPC H02G 3/088; H02G 3/083

(57) ABSTRACT

A housing for an electronic device may include a first housing part for receiving the electronic device and a second housing part for completely receiving the first housing part therein. A gap formed between the two housing parts may be sealed by both housing parts and filled with a potting material, while an interior of the first housing part is not filled with the potting material. The first housing part may be formed separately from the second housing part and spaced from the second housing part by a number of spacers to form the gap. The first housing part, including the spacers, may be dimensioned with respect to the second housing part such that it is insertable into a fixed spatial position within the second housing part in sliding contact between the spacers and the second housing part before the potting material substantially completely surrounds the first housing part.

### CROSS-REFERENCE TO RELATED APPLICATION

The present patent application claims priority, according to 35 U.S.C. § 119, from German Patent Application No. 10 2022 113 975.1 filed on Jun. 2, 2022, which is incorporated herein by reference in its entirety and for all purposes.

### TECHNICAL FIELD

Various exemplary embodiments relate to a housing for an electronic device. In particular, they also relate to housings for electrical ballasts with which semiconductor light sources are operated.

### BACKGROUND

Electronic devices, such as, in particular, electronic ballasts for operating light sources, are often set up in housings adapted for the application, which offer a certain degree of protection against contact by body parts, or the ingress of dirt, water, and moisture, etc., and also allow mechanical installation in the vicinity of the particular light sources. Beyond the conventional applications in the domestic (residential) field or in offices with power consumption of, for example, 10-100 W each, such devices are also used in the industrial field and can register, there, power consumption of, for example, up to 500 W or more. The requirements for heat dissipation and fire protection, for example, are increasing here and the corresponding housings are dimensioned accordingly and designed with suitable materials. For special applications, such as in larger greenhouses or similar, ballasts with even higher power consumptions can be considered, for example 600 W or 1200 W, without limiting generality.

Particularly in the example of the use of electrical ballasts for operating light sources in greenhouses, the question of the suitability of electrical equipment for the particular environmental conditions arises—as is generally the case in the entire outdoor area, but frequently also in the indoor area. In this context, the housing should be configured to provide protection against the ingress of moisture or water in particular. The aim is to protect people from hazards or to protect the relevant circuit components or the equipment they operate from failure, for example, due to water penetration, corrosion or a conductive film of moisture. Impairments due to mechanical effects (impacts, etc.) must also be taken into account to ensure reliable operation and safe use of the device.

In order to make it easier for users to select devices suitable for the particular application, so-called IP protection classes (IP: ingress protection) were introduced, which are also specified in standards such as DIN EN 60529 or ISO 20653. For the question of moisture, for example, the protection classes IP64, IP65, IP 66, IP67 and IP68 are relevant. The number “6” listed here in the first position indicates the presence of dust-tightness as well as complete protection against contact. The second-placed number “4” (i.e. IP64) indicates protection against splashing water from all sides, the number “5” (i.e. IP65) indicates protection against water jets from a nozzle at any angle, the number “6” (i.e. IP66) indicates protection against strong water jets, the number “7” indicates protection against temporary submersion, and the number “8” (i.e. IP68) indicates protection against permanent submersion (usually up to 1 m). These protection classes IP64 to IP68 thus indicate, in a graduated manner, approximately the scope of requirements to be fulfilled by the correspondingly equipped housings for the special fields of application indicated above (greenhouses, plantations, parks or gardens, outdoor areas, industrial applications, also with indoor areas, etc.).

This is usually achieved by means of housings with encapsulations. For example, the housing containing a complete electronic assembly is filled here with a solid or viscous potting material after curing, so that the electronic components are embedded in this potting material. This reduces phenomena such as discharges between the live components, absorbs shocks and vibrations and, in particular, prevents the ingress of water, moisture or corrosive agents from outside.

Thermosets or silicone rubber gels are used generally as potting materials (but also in the exemplary embodiments to be described below). Epoxy resins are also considered and are also very common. In the potting process, a corresponding electronic assembly is inserted into a prefabricated housing, the openings of which, such as for cable feed-throughs, etc.—except for the filling opening—are sealed to prevent the potting material from escaping before curing. The still liquid potting material is then filled into the filling opening.

When potting a housing that has an electronic ballast with electronic components mounted on a printed circuit board (e.g. in SMD design), potting materials with a low glass transition temperature, such as polyurethane or silicone, may be used because the forces that arise during the shrinkage process during the cooling or curing that follows the filling are lower in this case, which could then act on the components.

However, these advantages of complete potting are offset by aspects of reduced sustainability, increased costs with regard to the potting material, and increased weight. With regard to the aspect of sustainability, it should be noted that when the components are embedded in the potting material, recycling of the materials is problematic with regard to their separation from each other after the useful life of the device has expired. With regard to the cost of materials and weight, it should be noted that with suitably adapted housings it could be possible to reduce the volume occupied by the interior thereof, but then it would no longer be an option to use inexpensively available standard components such as continuous casting profiles, and therefore an increase in costs can then be expected in that respect.

Consequently, there is a need to save costs and reduce the effort involved in assembly. In addition, it can be an objective to improve the assembly accuracy.

### SUMMARY

According to one aspect, this can be taken into account by proposing a housing for an electronic device comprising a first housing part designed to receive the electronic device and a second housing part designed to completely receive the first housing part therein. A gap is formed between the first inner housing part and the second housing part and is sealed by both housing parts and filled with a potting material, while an interior of the first housing part accommodating the electronic device is not filled with the potting material.

The first housing part is formed as a part separate from the second housing part and is spaced from the second housing part by a number of spacers to form the gap. The spacers may be provided on the first inner housing part, on the second outer housing part, or as parts separate from both. Without limiting generality, it is also possible that the spacers are only temporarily introduced during potting to define the gap and then removed while still curing or cooling so that no spacers (or, as the case may be, only fewer spacers than before) are present in the finished end product.

The first housing part, including the spacers, is dimensioned here with respect to the second housing part such that it is insertable into a fixed spatial position within the second housing part in sliding contact between the spacers and the second housing part prior to a step of pouring the potting material, wherein the potting material substantially completely surrounds the first housing part.

As a result, the proposed housing has a double-shell structure due to the two separate housing parts, wherein the gap between the two housing parts is filled with the potting material, while the interior of the inner (first) housing part, on the other hand, accommodates only the electronic device, but is not filled with the potting material or is filled only with minor, ineffective quantities. The gap and the interior are hermetically sealed from each other by the inner (first) housing part to prevent the potting material from running in during the potting process. The potting material itself serves to protect the interior from moisture or water in the finished, for example, cured state or in the state simply cooled below the glass transition temperature, which it achieves by substantially completely enclosing the inner (first) housing part. The term “substantially” means here that individual projections such as the spacers, which are intended to establish at least a sliding contact between the two housing parts, or else a channel, which is also to be described below and accommodates a valve that allows moisture to escape from the interior after sealing but not to enter, may well still extend through the potting material, or indeed should do so in order to achieve the particular purpose. It is advantageous if there are no air holes in the potting material that allow the inner (first) housing part and the outer (second) housing part to face each other, or that allow them to even touch each other directly (without spacers or channels set up for moisture removal).

This design with moisture protection makes it possible to achieve the more demanding IP67 or even IP68 protection classes. At the same time, however, other advantages can also be achieved, such as primarily a considerable material saving in potting material, which no longer needs to fill the interior. According to exemplary embodiments, a material saving of 70% or more in potting material can be achieved in comparison with the conventional case in which the housing comprises only the second (outer) housing part proposed here, i.e. the first (inner) housing part is omitted.

Due to its material properties, silicone in particular can be considered as a potting material for a wide range of applications in which the above-mentioned IP67 or IP68 protection classes are achieved. In view of the market prices of silicone, a considerable cost reduction can be achieved by the proposed aspects while maintaining the protection classes. However, other materials such as plastics, especially thermosets, can also be considered, such as epoxy resins, crosslinkable polyurethanes and unsaturated polyester resins, tar, etc.

At the same time, however, the material saving also leads to a reduction in the weight of the finished component. On the one hand, this in turn allows a cost saving in the transport costs during production and especially in distribution. On the other hand, according to special exemplary embodiments, which concern applications in the industrial field and also, for example, in greenhouses, etc., this also results in advantages insofar as, with the total weights usually present here in the one- to two-digit kilogram range, the load-bearing capacity of the structures is relieved, for example at the rails or beams in the ceiling area to which the components are to be attached. In the specific example of greenhouses, these structures can also be steel profile frameworks with defined load limits. The material and weight saving also extends the field of applications at the same time. Furthermore, a reduction in the total combustible mass can also be a particular advantage.

Furthermore, the aspects proposed here can also significantly reduce the development time of the measures required for assembly.

A further advantage may also be, in particular, that sustainability is improved, namely if, after the service life of the component over its permanent service life, during disposal, the electronic components can be separated from the housing components in a simple manner. Because the electronic components are accommodated in the empty interior of the first (inner) housing part, they can be easily removed after disassembly and subjected to appropriate disposal in each case, which saves considerable time and costs. Electronic components containing hazardous substances such as arsenic can thus be identified very easily and treated individually, for example without silicone adhesions remaining on them.

According to one exemplary embodiment, the first inner housing part comprises a substantially cuboid base portion having an opening and a cover portion fitted over the opening to close off the interior. The cover portion may be flat, and may optionally include ribs or similar structures that reinforce the shape of the cover portion and/or aid in heat dissipation. In a simple, optional case, the structure may be proposed to be similar to a shoebox design. For example, the opening may correspond to one of the cuboid faces. During assembly, the structure allows easy insertion of, for example, a relevant printed circuit board with the electronic components and, if necessary, thermal pads on the upper side of the electronic components of the printed circuit board thereon. With the cover, the base portion can be closed quickly and securely. For automated production, this means very little effort.

According to an exemplary embodiment of an electronic device building thereon, both the base portion and the cover portion are provided with spacers. In the mounted state of the cover portion and in the inserted state of the first (inner) housing part (in the second, outer housing part), at least some of the spacers of the base portion and the cover portion are thus in each case in contact with opposing inner walls of the second housing part. In particular, the cover portion may be held here pressed against the base portion. The spacers may be, for example, flat plate-like portions protruding from the surface of the base portion and the cover portion. They may protrude vertically, but they may also protrude at an angle. They may also be formed integrally with the base and/or cover portions. The spacers may have some flexibility or resilience to resiliently contact the opposing inner wall of the second outer housing portion. An oversize is not necessarily required—what is relevant in this exemplary embodiment is that the spacers allow the first inner housing portion to occupy a secure and stable position within the second outer housing portion; the predetermined gap can be achieved substantially all around, while still maintaining a displaceability of the first inner housing portion relative to the second outer housing portion by gentle sliding contact.

According to a further optional refinement, in the housing for an electronic device according to one of the two aforementioned exemplary embodiments, recesses are provided in the base portion and/or in the cover portion, starting from a particular edge, into which sliders are inserted which are designed to seal the recesses, for example as in a tongue-and-groove connection and optionally plus a ring seal, for example made of a rubber, inserted into the groove. Passages, again with sealing elements, are provided in each of the sliders for feed-throughs of electronic cables configured for power supply or output of the electronic device. The sliders may be pre-fitted to the cables during manufacture. With this design, a secure seal and at the same time a simple assembly of the component is achieved.

In the exemplary embodiments, the cover portion may comprise a plate made of metal, in particular aluminum, wherein the plate seals the opening substantially tightly. For this purpose, a ring seal (O-ring) or a seal with a different cross-sectional shape made of rubber may also be provided.

In such a case, the cover portion may optionally comprise a retaining frame, such as made of plastic, engaging around the plate, wherein the retaining frame carries the relevant spacers of the cover portion and further comprises fastening elements capable of fixing the cover portion to the base portion during assembly. Alternatively, the corresponding snap hooks, or latching elements may also be formed on the tray formed by the base portion. In this way, the plate can seal the container substantially tightly and at the same time serve to dissipate heat, while the retaining frame performs mechanical functions (defining the gap and fixing the cover to the base portion or pressing it against the base portion). Optionally, the retaining frame, like the base portion, can be formed, for example, only of a plastic. A multi-part design of the retaining frame as well as the use of other materials such as metal or ceramic is also possible.

The plate, on the other hand, can be connected to heat-conducting elements of the electronic device directly or indirectly via heat-conducting thermal pads, pastes or adhesives, or via additional metal elements, in particular plates and/or screws, in order to dissipate the heat. The heat is transferred here from the inside—it is generated in the electronic components on the printed circuit board—for example to the thermal pads or the thermal conductive paste (thermal grease) to the plate made of aluminum and from there to the potting material (in this case silicone) towards the outer housing. For the silicone adjacent after filling (if silicone is used), there can be a sufficient thermal conduction coefficient for the application, so that sufficient cooling of the electronic components is ensured during operation.

According to an exemplary embodiment, the second housing part comprises a hollow tube profile and two opposing end plates attachable at the end faces to the two tube openings. As indicated above, this allows the first (inner) housing part—with the spacers sliding on the inner surface of the tube—to be inserted into its defined spatial position through one of the two tube openings. This makes assembly very easy and allows the use of easily cut-to-size stand components which are available on the market very inexpensively.

This applies in particular if, for example, an extrusion or continuous casting profile, especially one made of aluminum, is used for the hollow tube profile.

Optionally, the hollow tube profile can also have a substantially rectangular cross-section into which the cuboid first (inner) housing part proposed above can be inserted along its longitudinal axis. The outer and/or inner surface may have a structure (corrugation, etc.) for better cooling.

Further, the second outer housing part may include one or more flanges for attachment to an external superstructure (wall of a building, framework of a greenhouse, etc.). According to a special embodiment, a longitudinally extending bracket may also be provided on the outside of the tube profile and is plugged—or slid—onto a bracket on the framework or the wall with a complementary cross-sectional profile, for example, a T-shape.

Furthermore, at least one of the end plates can optionally additionally have sealing cable feed-throughs for the electronic cables of the electronic device, the position of which, in the assembled state, is opposite the sliders inserted into the recesses of the base portion.

According to a particular aspect, an outwardly projecting through-channel may be formed in an end outer wall of the base portion or the cover portion, which through-channel, when assembled, extends through the gap to one of the two end plates and is open to the outside therethrough, wherein a valve is provided in the through-channel for pressure equalization and for the possibility to remove air humidity from the interior of the assembly, said valve being permeable to air in both directions but permeable to moisture in only an outward direction.

Two functions are fulfilled by the valve: on the one hand, the valve acts through a diaphragm to relieve the excess pressure in the interior (i.e., a pressure equalization with the environment) when the electronic assembly inside the first (inner) housing part heats up during operation, and on the other hand, through the same or an additional diaphragm, by preventing the accumulation of moisture inside due to the negative pressure created when the electronic assembly inside cools down (even after curing). Otherwise, under certain circumstances, moisture accumulating in the interior of the first (inner) housing part could lead to a loss of function and safety of the printed circuit board and of the installed electronic components.

According to another aspect combinable with some or all of the above examples and aspects, a housing for an electronic device is proposed in which the proportion of the volume of the filled gap to a total volume composed of the gap and the interior, excluding the volume occupied by the electronic device, is 50% or less, such as 40% or less, or 30% or less, up to 20% or less. The smaller the proportion of the gap that is filled, the greater the material, cost and weight savings.

The aforementioned aspects and embodiments prove particularly advantageous when the housing includes an electronic device comprising a printed circuit board having electronic components mounted thereon, wherein the electronic device may be an electronic ballast for semiconductor light sources, which may further have a power consumption of 500 watts or more. Clear advantages are also seen with power consumptions as low as 300 watts or more.

Further advantages, features and details of the various aspects can be found in the claims, the following description of non-limiting embodiments and the drawings. In the figures, the same reference signs denote the same features and functions.

### BRIEF DESCRIPTION OF THE DRAWINGS

The drawings show:

FIG. 1 a perspective view of a base portion of a first inner housing part of a housing according to an exemplary embodiment;

FIG. 2 a partial perspective view of the process of placing an electronic device in the first inner housing part of FIG. 1;

FIG. 3 a perspective view of the state after completion of placement in FIG. 2;

FIG. 4 a perspective view of the process of providing a ring seal;

FIG. 5 a perspective view of a plate of a cover portion of the first inner housing part being placed on the base portion as shown in FIG. 4;

FIG. 6 a perspective view of a retaining frame being placed on the plate and then snapped onto the edge of the opening of the base portion;

FIG. 7 an enlarged, partial cross-sectional view through the assembled first inner housing part with details of the fixing of the cover portion to the base portion, from the perspective of the end face;

FIG. 8 as FIG. 7, but as a side view, from the perspective of the end face;

FIG. 9 a perspective view of a process of inserting the assembled first inner housing part into a tube profile of a second outer housing part according to the exemplary embodiment;

FIG. 10 a perspective view of an outer side of a first end plate for closing the tube profile shown in FIG. 9;

FIG. 11 a perspective view of an inner side of the first end plate from FIG. 10;

FIG. 12 a perspective view from the side and above the first end plate attached to the tube profile;

FIG. 13 a perspective view from the side and below the first end plate attached to the tube profile;

FIG. 14 a perspective section of the housing assembled from the first inner housing part and the second outer housing part according to the exemplary embodiment with a valve for pressure equalization and the possibility of removing air humidity from the interior of the assembly, in an enlarged view;

FIG. 15 a side sectional view of the assembled housing with potting material filled therein (in the figure, the surface lying at an angle to the longitudinal axis can be seen at the top);

FIG. 16 an enlarged detail of a perspective cut through the housing from FIG. 15; and

FIG. 17 a perspective exterior view of the assembled housing according to the exemplary embodiment.

### DETAILED DESCRIPTION

In the following description of non-limiting embodiments, it should be understood that the present disclosure of the various aspects is not limited to the details of the structure and arrangement of the components as presented in the following description and figures. The exemplary embodiments may be put into practice or carried out in various ways. It should further be appreciated that the expressions and terminology used herein are used for the purpose of specific description only, and they should not be construed as such in a limiting manner by those skilled in the art. Furthermore, in the following description, identical reference signs in the various exemplary embodiments or figures denote identical or similar features or objects, so that in some cases a repeated detailed description thereof is omitted in order to preserve the conciseness and clarity of the presentation.

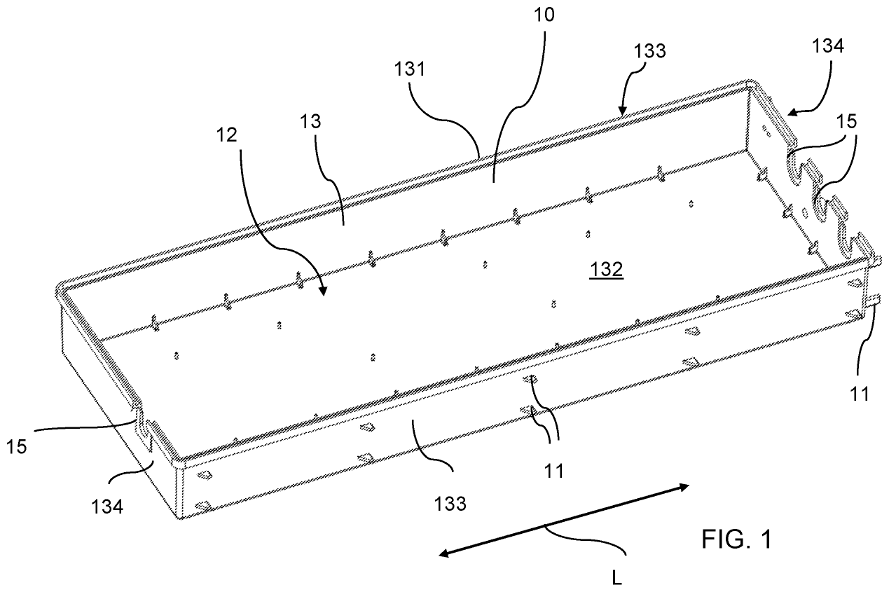

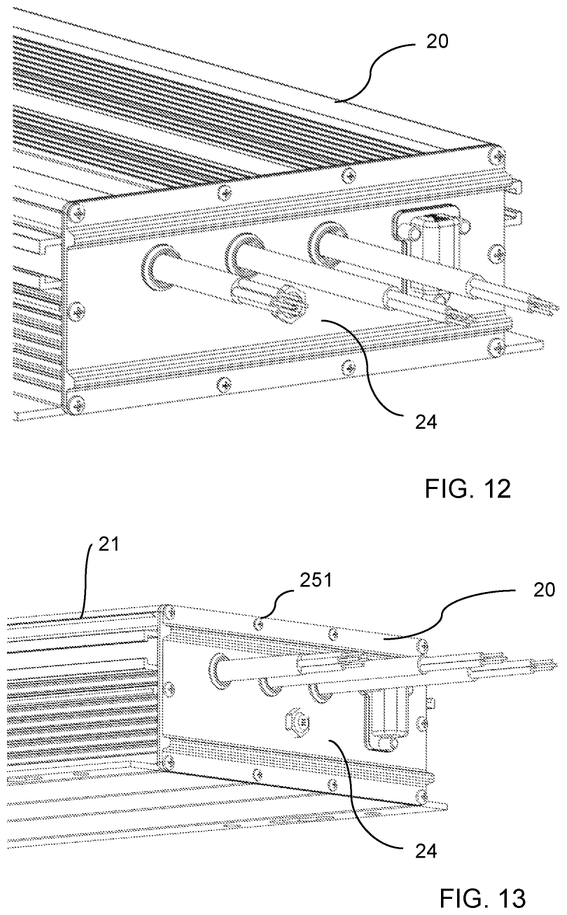

FIGS. 12-17 show a non-limiting embodiment of a housing 1 in various perspectives and sections, while for clarity FIGS. 1-11 reflect individual steps of the assembly of the housing 1 starting from the provision of a base portion 13 of a first inner housing part 10. For the sake of comprehensibility of the individual components, we will start with description of the assembly.

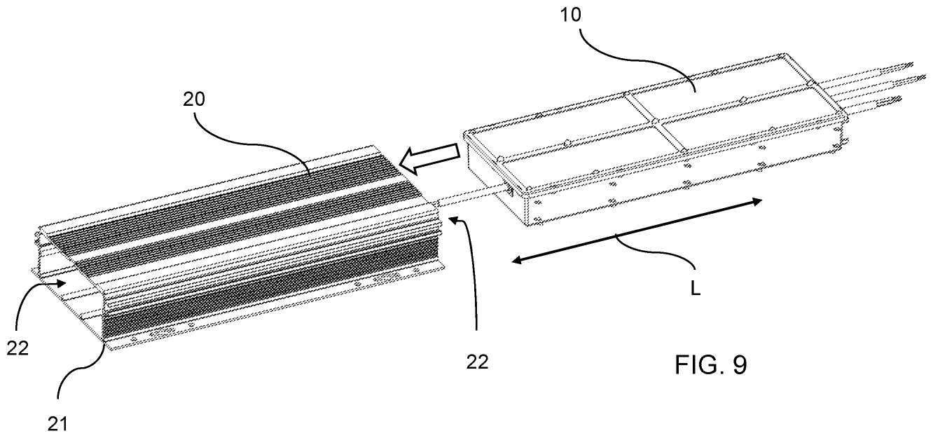

FIG. 1 shows an initially provided base portion 13 of a first inner housing part 10 (hereinafter referred to only as “inner housing part”) in perspective view, wherein the base portion 13 has a box-shaped or cuboid structure with a rectangular bottom 132 and four perpendicular or parallel upright side walls 133, 134. The side walls 133 extend parallel to a longitudinal axis L (cf. FIG. 9) and the end-face side walls 134 extend substantially perpendicularly to the longitudinal axis L. The side walls 133, 134 have a substantially coinciding height and form an edge on the side facing away from the bottom 132, through which an opening 131 is formed in the cuboid shape.

The bottom 132 and the four side walls 133, 134 form an interior 12, in which—as indicated without reference signs in FIG. 1—reinforcing structures can be arranged, for example at the transition points between the walls, or filigree support structures distributed over the area of the bottom 132 for supporting the printed circuit board 96 to be inserted later.

At the end face, i.e. in the side walls 134, starting from the edge forming the opening 131, U-shaped recesses 15 are provided, the function of which is described below. Projections serving as spacers 11 are also arranged at regular intervals from one another on the outer surfaces of the side walls 133 and at least one end-face side wall 134. The base portion 13 shown in FIG. 1 may be formed integrally, for example by injection molding, from a plastic or a resin.

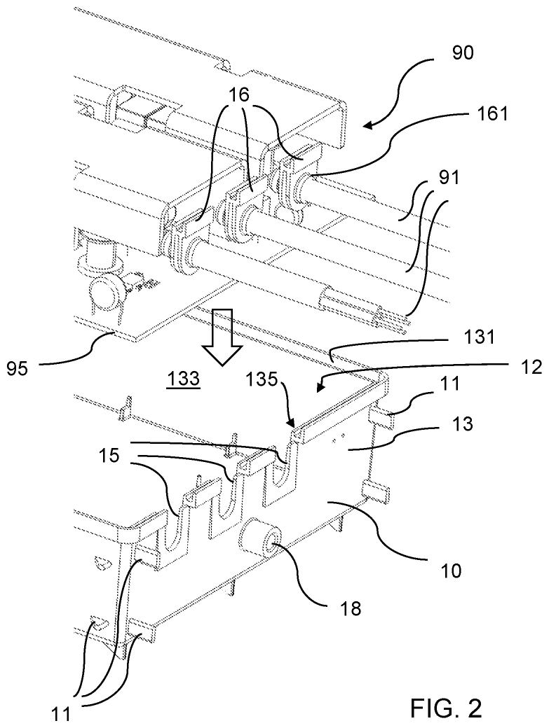

In FIG. 2, the process of placing an electronic device 90 in the inner housing part 10 of FIG. 1 is shown at least for an end-face section of the base portion 13. The electronic device 90 may be an electronic ballast (EB) for operating luminaires with, for example, semiconductor light sources (LEDs). Such electronic ballasts are widely known in the technical field, and therefore reference can be made here to relevant literature with respect to the components. In the example, the electronic ballast is designed for a power of, for example, 600 W or 1200 W. The electronic device 90 comprises a printed circuit board 95 on which the electronic components (e.g. capacitors, resistors, integrated circuits comprising transistors, etc.) are arranged and interconnected in a known manner.

In FIG. 2, three electrical cables 91 are shown purely by way of example, which form corresponding outgoing line strands for supplying the illuminants, mostly LEDs (not shown), with power and with open-loop and closed-loop control elements. Sliders 16 are plugged over the cables 91 and have a U-shape in plan view that matches the corresponding U-shape of the recesses 15. In this case, a groove is formed in the outer circumference of the U-shape of the sliders 16, into which the corresponding wall portion of the end side face 134 enters in the region of the recesses 15, so that the sliders can be inserted into the recesses 15 in a form-fitting manner when the electronic device is inserted into the interior 12 of the base portion 13. For the cable feed-through, the sliders 16 have suitably shaped, for example round, passages 161, optionally with tightly fitting ring seals made of rubber. With the aid of the sliders 16, the electric cables 91 are received in the corresponding recesses of the base portion 13.

It can also be seen in FIG. 2 that the edge forming the opening 131 of the base portion 13 has a circumferential groove 135 which is interrupted by the recesses 15. However, this gap in the groove 135 is again closed by the sliders 16, because these also have a correspondingly designed groove portion.

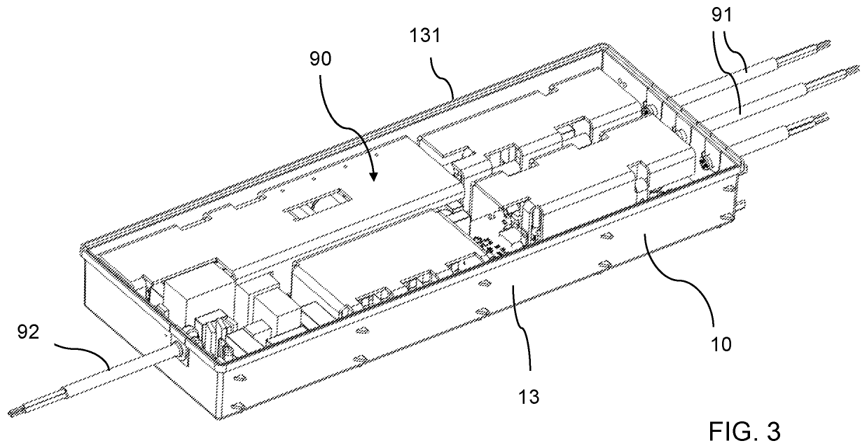

In FIG. 3, the state after completion of io8ewplacement of the electronic device 90 with the printed circuit board 90 towards the bottom 132 of the base portion 13 (downward) is shown. It should be noted that also on the opposite end face of the base portion 13 the corresponding recess 15 is closed analogously with a suitable slider 16 and associated electric cable 92 (power supply for example with mains voltage).

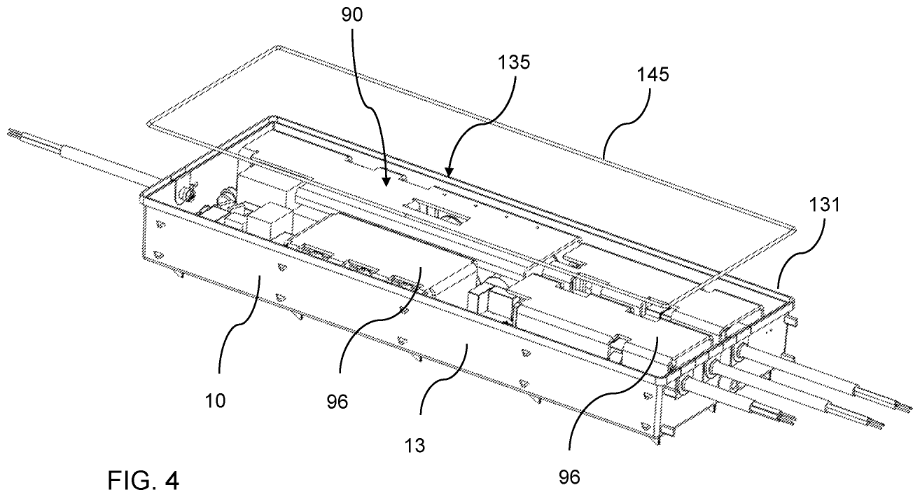

In FIG. 4, a ring seal (O-ring) 145 is provided which is precisely configured to fit into the closed circumferential groove 135 of the frame of the opening 131. The ring seal 145 may be prefabricated from rubber or silicone in a suitable rectangular or circular shape, etc. Alternatively, the seal may be created using a cartridge gun, for example.

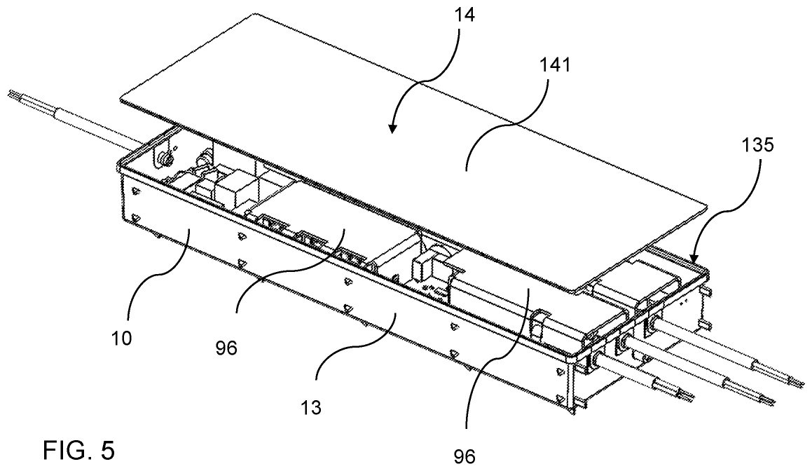

FIG. 5 shows the subsequent placement of a flat plate 141 (such as made of metal) of a cover portion 14 on the base portion 13.

The plate 141 may be made of aluminum or other thermally conductive materials and may have cutouts or apertures. It has a rectangular shape matching the edge of the opening 131. The edge forming the circumferential groove 135 has an inner wall and an outer wall. The outer wall protrudes slightly upward (away from the bottom 132) relative to the inner wall. The plate 141 rests on the ring seal 145 filling the groove 135, and its four edges fit snugly against the raised outer walls of the edge of the opening 131.

As can also be seen from FIG. 5, individual electronic components of the electronic device 90 are provided with thermally conductive metal surfaces 96 in the interior 12 of the base portion 13. These metal surfaces 96 simultaneously form contact surfaces to the thermal pads which are in contact with the plate 141, so that they are in contact with each other in the installed state. In this way, heat can be dissipated from the electronic device 90 during operation.

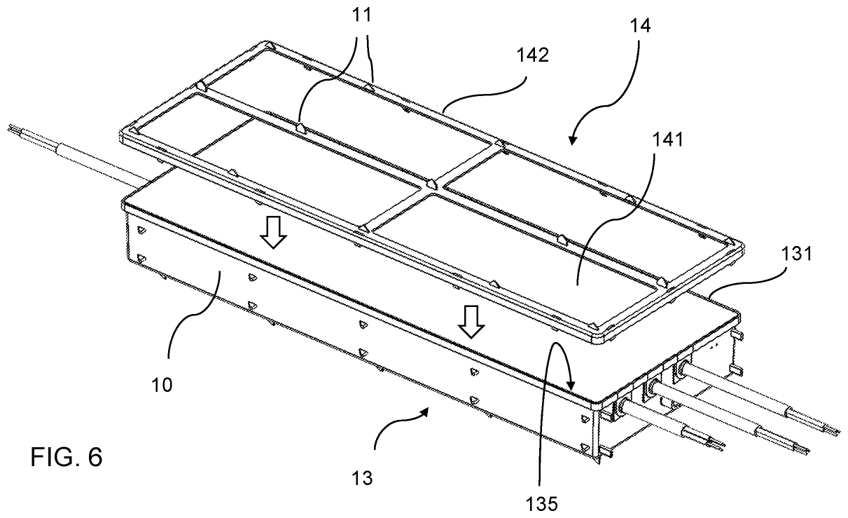

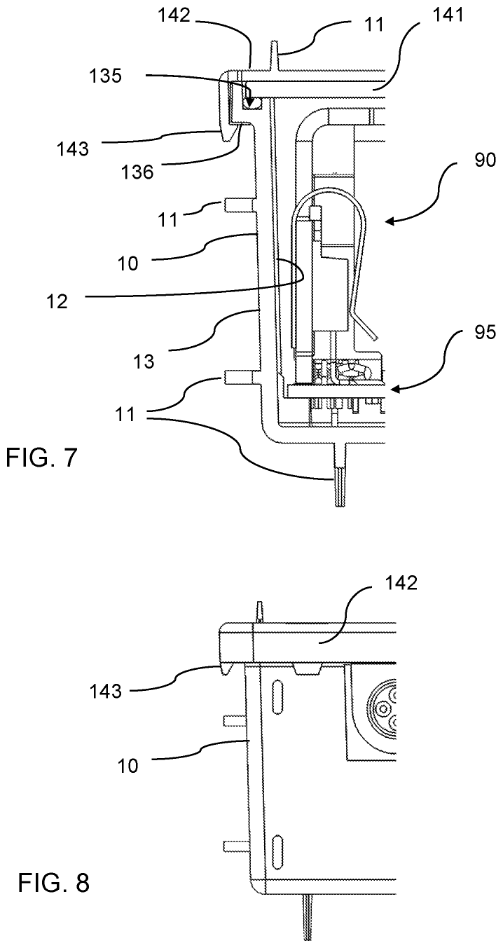

FIG. 6 shows the placement of a flat retaining frame 142 on the plate 141 and the edge of the base portion 13. Like the base portion 13, the retaining frame 142 may be made of a plastic or metal, or a resin. The retaining frame 142 has a rectangular outer frame that matches the edge of the base portion 13. The outer frame is reinforced internally, for example by braces arranged crosswise. The retaining frame 142 serves to fix the plate 141 to the base portion 13 and to provide further spacers 11 (see FIGS. 7 and 8), by means of which further pressure can be applied to the plate 141 to press it against the base portion 13. It should be noted that the retaining frame can be made in one or more parts.

FIG. 7 shows a cross-sectional view through the now fully assembled inner housing part 10. The electronic device 90 is now located in the encapsulated interior 12 of the inner housing part 10. The plate 141 of the cover portion 14 rests on the seal 145 in the groove 135 and is pressed against and/or fixed in place by the retaining frame 142, which for this purpose has a latching element 143 (latching lugs) which protrude downwards and resiliently grip around a corresponding projection 136 of the base portion 13. This projection 136 simultaneously forms the edge of the base portion 13 with the groove 135 therein.

It can also be seen from FIG. 7 that both the cover portion 14 (retaining frame 142) and the base portion 13 (side walls 133, 134 and bottom 132) have spacers 11. FIG. 8 shows a similar detail of the inner housing portion 10 in the same viewing direction, but in a frontal view rather than in cross-section.

FIG. 9 illustrates the process of inserting the assembled inner housing part 10 into a tube profile 21 of a second outer housing part 20 (hereinafter referred to only as “outer housing part” 20) according to the exemplary embodiment. The tube profile 21 is formed, for example, as an extruded continuous casting aluminum profile which has been cut to a suitable length to accommodate the inner housing portion 10. This cutting to size, as in the case of running yard goods, significantly reduces production costs. As shown in FIG. 9, the inner housing part 10 is inserted along its longitudinal or transverse axis L into one of the two openings 22 of the tube profile 21 and pushed completely into the tube profile 21. The position of the inner housing part 10 within the tube profile 21 is determined here by the spacers 11. More precisely, the inner housing part 10 is dimensioned in cross-section together with the spacers 11 in such a way that when the inner housing part 10 is pushed into the tube profile 21 of the outer housing part 20, the spacers 11 are in contact with the four inner sides of the tube profile 21 with slight pressure and slide along them.

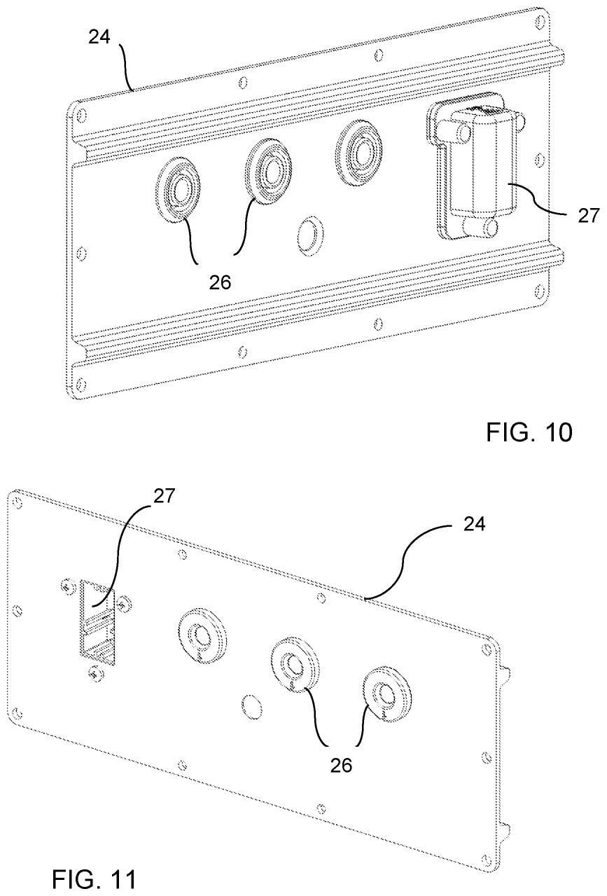

FIGS. 10 and 11 show an outer side and inner side, respectively, of a first end plate 24 for closing the tube profile shown in FIG. 9. This is the end plate 24 which, in the installed state, is opposite that end face 134 of the base portion 13 which has those three recesses 15 for the cable feed-throughs, as shown in FIG. 2. Accordingly, three round cable feed-throughs 26 are shown in the first end plate 24 at the appropriate positions. Further, a receptacle 27 for an NFC circuit of the electronic device 90 is provided.

In FIGS. 12 and 13, respectively, a perspective view is shown of the first end plate 24 subsequently fastened to the tube profile 21 by fastening means 251 (e.g., screws), with cables 91 passed through.

In FIG. 14, the housing assembled from the inner housing part and the outer housing part 20 according to the exemplary embodiment is shown in cross section. A gap 30 is formed between an inner side 28 of the tube profile 21 and an outer side of the side wall 133 of the base portion 13 by the spacers 11, said gap being encapsulated by the two housing parts 10, 20. The spacers 11, which slide during insertion, are formed on all four lateral sides (side walls 133, 134, bottom 132, retaining frame 142 on the cover portion 14) of the inner housing part 10, as well as on one of the two end faces 134. On the other of the two end faces 134 of the base portion 13, on the other hand—as shown in FIG. 2—only one tubular through-channel 18 is formed, which is, however, designed to contact the corresponding end plate 24 and thus also to define a spacing.

The through-channel 18 opens into the interior 12 of the inner housing part 10. A valve 19 is press-fitted or screwed via a metric thread, or also glued or welded, into the outer opening of the through-channel 18 for pressure equalization and the possibility of removing air humidity from the interior of the assembly. In particular, the valve 19 is permeable to air in both directions, but permeable to moisture in only an outward direction. Thus, pressure equalization is possible at any time (during manufacture or subsequent cooling, in operation), while any moisture is kept away from the electronic device 90.

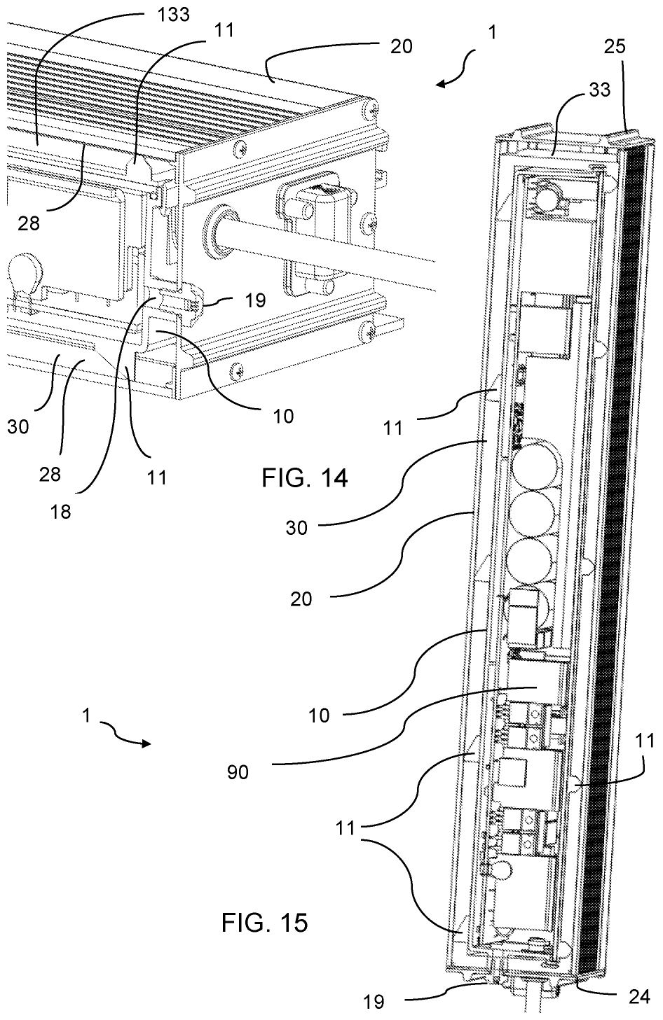

FIG. 15 shows a side sectional view of the assembled housing with the potting material filled therein. For filling, the housing 1 is set up as shown with its longitudinal axis substantially upright—but still inclined to about 70 degrees—(valve side downward) and potted from the opening 22 of the tube profile 21, which is not yet closed (second end plate 25), for example with silicone as potting material 32. This fills the gap 30 almost completely. The housing 1 can also additionally be tilted about a second axis.

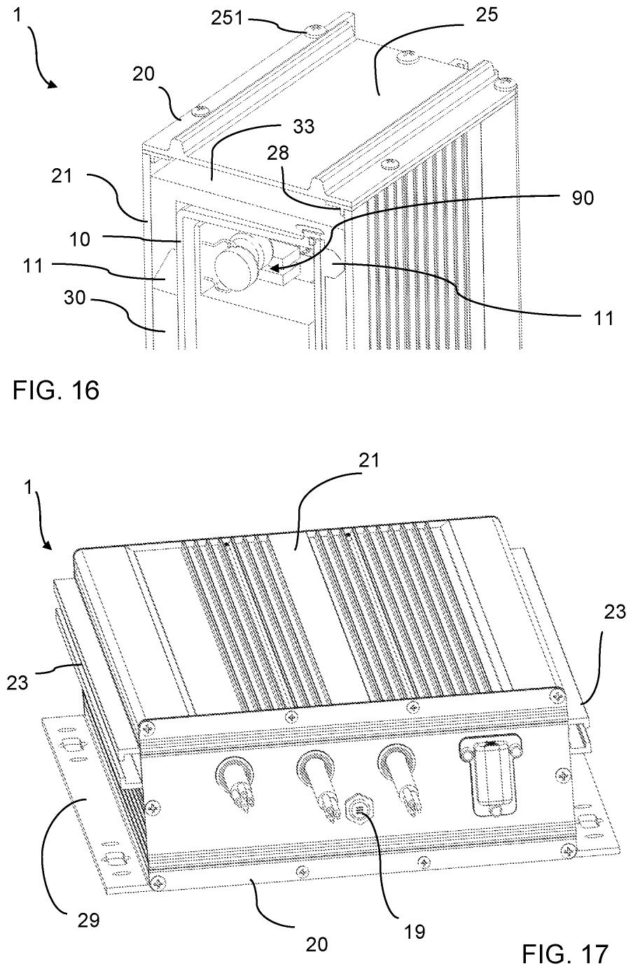

FIG. 16 shows the upper part of the filled housing 1 in greater detail. Lastly, FIG. 17 shows a perspective exterior view of the assembled finished housing according to the exemplary embodiment.

### LIST OF REFERENCE SIGNS

1 housing
10 first (inner) housing part
11 spacer
12 interior
13 base portion
131 opening (edge) of the base portion
132 bottom of the base portion
133 side outer faces of the base portion
134 end outer faces of the base portion
135 edge groove
136 engagement projection
14 cover portion
142 holding frame
143 engagement element
15 recess
16 slider
161 passage for cable lead-through
20 second outer housing part
21 tube profile
22 end opening in the tube profile
23 mounting rail (with undercut)
24 first end-face plate
25 second end-face plate
251 fastening means for end-face plate (screws)
26 cable feed-throughs in end-face plate
27 receptacle for NFC circuit
28 ring seal (for end-plate mounting)
29 mounting flange
30 gap
33 potting material (silicone)
90 electronic device
91 electronic cable (output to light sources)
92 electronic cable (power supply)
93 outlet opening for laser beam
96 printed circuit board
L longitudinal axis (both housing parts)

1. A housing for an electronic device comprising:
a first housing part configured to receive the electronic device; and
a second housing part configured to completely receive the first housing part therein;
wherein a gap formed between the first housing part and the second housing part is sealed by both housing parts and filled with a potting material, whereas an interior of the first housing part accommodating the electronic device is not filled with the potting material;
wherein the first housing part is formed as a part separate from the second housing part and is spaced from the second housing part by a number of spacers to form the gap;
wherein the first housing part, including the spacers, is dimensioned with respect to the second housing part such that the first housing part is insertable into a fixed spatial position within the second housing part in sliding contact between the spacers and the second housing part prior to pouring the potting material, wherein the potting material substantially completely surrounds the first housing part.

2. The housing for an electronic device as claimed in claim 1, wherein
the first housing part comprises a substantially cuboid base portion with an opening and a cover portion fitted onto the opening and closing off the interior.

3. The housing for an electronic device as claimed in claim 2, wherein
both the base portion and the cover portion are provided with spacers, wherein in the fitted state of the cover portion and in the inserted state of the first housing part at least some of the spacers of the base portion and the cover portion are in contact in each case with opposing inner walls of the second housing part, in such a way that the cover portion is held pressed against the base portion.

4. The housing for an electronic device as claimed in claim 2, further comprising
recesses provided in the base portion and/or in the cover portion, starting from an edge of the relevant portion and into which sliders are inserted so as to seal the recesses, wherein passages are provided in each of the sliders for feed-throughs of electric cables for power supply or output of the electronic device.

5. The housing for an electronic device as claimed in claim 2, wherein
the cover portion comprises a plate, wherein the plate closes off the opening substantially sealingly.

6. The housing for an electronic device as claimed in claim wherein
the cover portion comprises a retaining frame engaging around the plate, wherein the retaining frame carries the relevant spacers of the cover portion, and further comprises fastening elements capable of affixing the cover portion to the base portion during assembly.

7. The housing for an electronic device as claimed in claim 5, wherein
the plate is connected to heat-conducting elements of the electronic device directly or indirectly via heat-conducting pastes, thermal pads, adhesives, via metal elements, via non-metal elements, spring elements, or combinations thereof.

8. The housing for an electronic device as claimed in claim 1, wherein
the second housing part comprises a hollow tube profile and two opposing end plates attached at the end faces to the two tube openings, wherein the first housing part, with the spacers sliding on the inner surface of the tube, is inserted into its defined spatial position through one of the two tube openings.

9. The housing for an electronic device as claimed in claim 8, wherein
the hollow tube profile is an extrusion or continuous casting profile.

10. The housing for an electronic device as claimed in claim 8, wherein
the hollow tube profile has a substantially rectangular cross-section.

11. The housing for an electronic device as claimed in claim 8, wherein
the first housing part is inserted into the hollow tube profile along its longitudinal or transverse axis.

12. The housing for an electronic device as claimed in claim 8, further comprising recesses provided in the base portion and/or in the cover portion, starting from an edge of the relevant portion and into which sliders are inserted so as to seal the recesses, wherein passages are provided in each of the sliders for feed-throughs of electric cables for power supply or output of the electronic device;
wherein at least one of the end plates has sealing cable feed-throughs for electric cables, the position of which, in the assembled state, is opposite the sliders inserted into the recesses of the base portion.

13. The housing for an electronic device as claimed in claim 1, wherein
an outwardly projecting through-channel is formed in an end-face outer wall of the base portion or the cover portion, which through-channel extends through the gap to one of the two end plates and is open to the outside therethrough, wherein a valve is provided in the through-channel for pressure equalization and for the possibility to remove air humidity from the interior of the assembly, said valve being permeable to air in both directions but permeable to moisture in only an outward direction.

14. The housing for an electronic device as claimed in claim 1, wherein
the proportion of the volume of the filled gap to a total volume composed of the gap and the interior—excluding the volume occupied by the electronic device—is 50% or less.

15. The housing for an electronic device as claimed in claim 1, wherein
the potting material is silicone, epoxy resin, tar, or combinations thereof.

16. The housing for an electronic device as claimed in claim 1, wherein
the electronic device comprises a printed circuit board with electronic components mounted thereon, wherein
the electronic device is an electronic ballast for semiconductor light sources, wherein the electronic device has a power consumption of 500 watts or more.
